(19) United States
(12) Patent Application Publication
(10) Pub. No.: US 2024/0229223 A9
(43) Pub. Date: Jul. 11, 2024

(54) DEPOSITION APPARATUS

(71) Applicant: SAMSUNG DISPLAY CO., LTD., Yongin-si (KR)

(72) Inventors: JONGBUN HAN, Yongin-si (KR); INAE HAN, Yongin-si (KR); Gan Young PARK, Yongin-si (KR); SUNGJONG PARK, Yongin-si (KR); DONGKIUN SEO, Yongin-si (KR)

(21) Appl. No.: 18/489,608

(22) Filed: Oct. 18, 2023

(30) Foreign Application Priority Data
Oct. 24, 2022 (KR) 10-2022-0137620

(51) Int. Cl. C23C 14/24

(52) U.S. Cl. CPC C23C 14/243; H10K 71/135

(57) ABSTRACT

A deposition apparatus includes: a vaporization portion to vaporize a first material, a second material, and a third material different from each other; and a first nozzle portion connected adjacent to the vaporization portion. The first nozzle portion includes: a first nozzle hole to discharge the first material; a second nozzle hole adjacent to the first nozzle hole and to discharge the second material; and a third nozzle hole adjacent to the first nozzle hole and the second nozzle hole and to discharge the third material.

### CROSS-REFERENCE TO RELATED APPLICATION

This application claims priority to and the benefit of Korean Patent Application No. 10-2022-0137620, filed on Oct. 24, 2022 in the Korean Intellectual Property Office, the entire content of which is incorporated herein by reference.

### BACKGROUND

### 1. Field

Aspects of embodiments of the present disclosure relate to a deposition apparatus.

### 2. Description of the Related Art

In general, a deposition apparatus includes a plurality of nozzles discharging an organic material forming an organic light emitting layer above or on a substrate.

Each of the plurality of nozzles included in a conventional deposition apparatus discharges one organic material.

A light emitting layer of the organic light emitting layer formed at the substrate is deposited by mixing a plurality of organic materials such as a host, a dopant, and the like.

However, in the conventional deposition apparatus, each of the plurality of nozzles for discharging the one organic material is spaced apart from each other to discharge each of the plurality of organic materials to be formed as the light emitting layer of the organic light emitting layer to the substrate, and there is a problem in which the organic light emitting layer is non-uniformly formed because the light emitting layer deposited on the substrate is non-uniformly formed.

The above information disclosed in this Background section is provided for enhancement of understanding of the background of the disclosure, and, therefore, it may contain information that does not form the prior art that is already known in this country to a person of ordinary skill in the art.

### SUMMARY

According to an aspect of embodiments of the present disclosure, a deposition apparatus to uniformly form an organic light emitting layer above or on a substrate is provided.

According to one or more embodiments, a deposition apparatus includes: a vaporization portion to vaporize a first material, a second material, and a third material different from each other; and a first nozzle portion connected adjacent to the vaporization portion. The first nozzle portion includes: a first nozzle hole to discharge the first material; a second nozzle hole adjacent to the first nozzle hole and to discharge the second material; and a third nozzle hole adjacent to the first nozzle hole and the second nozzle hole and to discharge the third material.

The vaporization portion may include: a first crucible to vaporize the first material; a second crucible adjacent to the first crucible and to vaporize the second material; and a third crucible adjacent to the second crucible and to vaporize the third material.

Insides of the first crucible, the second crucible, and the third crucible may be spaced from each other.

The first nozzle portion may further include: a first connection portion connected to the vaporization portion and through which the first material passes; a second connection portion adjacent to the first connection portion, connected to the vaporization portion, and through which the second material passes; and a third connection portion adjacent to the second connection portion, connected to the vaporization portion, and through which the third material passes.

Insides of the first connection portion, the second connection portion, and the third connection portion may be spaced from each other.

The first nozzle portion may further include: a first channel connected between the first connection portion and the first nozzle hole; a second channel adjacent to the first channel and connected between the second connection portion and the second nozzle hole; and a third channel adjacent to the second channel and connected between the third connection portion and the third nozzle hole.

Insides of the first channel, the second channel, and the third channel may be spaced from each other.

The second channel may be between the first channel and the third channel.

A shape of an inner space of the first channel may be symmetrical to a shape of an inner space of the third channel, and a shape of an inner space of the second channel may be different from the shape of the inner space of the first channel and the shape of the inner space of the third channel.

An internal cross-sectional area of the first channel may decrease as the first channel extends from the first connection portion to the first nozzle hole, an internal cross-sectional area of the second channel may decrease as the second channel extends from the second connection portion to the second nozzle hole, and an internal cross-sectional area of the third channel may decrease as the third channel extends from the third connection portion to the third nozzle hole.

The first nozzle portion may further include a first heater to heat the first connection portion, the first channel, the second connection portion, the second channel, the third connection portion, and the third channel.

The first nozzle hole, the second nozzle hole, and the third nozzle hole of the first nozzle portion may be located at a same (same or substantially same) region.

After the first material, the second material, and the third material are discharged from the first nozzle hole, the second nozzle hole, and the third nozzle hole, the discharged first, second, and third materials may be mixed at an upper side of the first nozzle portion.

The first nozzle portion may further include a first angle limiting portion around (e.g., surrounding) the first nozzle hole, the second nozzle hole, and the third nozzle hole.

The deposition apparatus may further include a pipe portion connected between an upper portion of the vaporization portion and a lower portion of the first nozzle portion.

The deposition apparatus may further include a second nozzle portion adjacent to the first nozzle portion and including a fourth nozzle hole to discharge a fourth material.

The second nozzle portion may further include a fourth crucible to vaporize the fourth material.

The second nozzle portion may further include a second heater to heat the fourth crucible.

The second nozzle portion may further include a second angle limiting portion around (e.g., surrounding) the fourth nozzle hole.

According to one or more embodiments, a deposition apparatus includes: a vaporization portion to vaporize a plurality of different materials; a nozzle portion connected adjacent to the vaporization portion and including a nozzle hole to discharge a material of the plurality of materials and another nozzle hole adjacent to the nozzle hole and to discharge another material of the plurality of materials; and at least one other nozzle portion adjacent to the nozzle portion and including another nozzle hole to discharge another material.

According to an aspect of embodiments of the present disclosure, a deposition apparatus to uniformly form an organic light emitting layer above or on a substrate is provided.

### BRIEF DESCRIPTION OF THE DRAWINGS

FIG. 1 is a plane view illustrating a deposition apparatus according to an embodiment.

FIG. 2 is a side view illustrating the deposition apparatus of FIG. 1.

FIG. 3 is a longitudinal cross-sectional view illustrating a first nozzle portion of the deposition apparatus of FIG. 1.

FIG. 4 is a plane view illustrating a deposition apparatus according to another embodiment.

FIG. 5 is a longitudinal cross-sectional view illustrating a first nozzle portion and a second nozzle portion of the deposition apparatus of FIG. 4.

FIG. 6 is a longitudinal cross-sectional view illustrating a nozzle portion and another nozzle portion of a deposition apparatus according to another embodiment.

### DETAILED DESCRIPTION

The present disclosure will be described more fully herein with reference to the accompanying drawings, in which some embodiments of the disclosure are shown. As those skilled in the art would realize, the described embodiments may be modified in various different ways, without departing from the spirit or scope of the present disclosure.

In order to clearly describe the present disclosure, parts or portions that are irrelevant to the description may be omitted, and same or similar constituent elements throughout the specification are denoted by the same reference numerals.

Further, in the drawings, the size and thickness of each element may be arbitrarily illustrated for ease of description, and the present disclosure is not necessarily limited to those illustrated in the drawings. In the drawings, the thicknesses of layers, films, panels, regions, areas, etc., may be exaggerated for clarity. In the drawings, for ease of description, the thicknesses of some layers and areas may be exaggerated.

It is to be understood that when an element such as a layer, film, region, area, substrate, plate, or constituent element is referred to as being “on” or “above” another element, it may be directly on the other element or one or more intervening elements may also be present. In contrast, when an element is referred to as being “directly on” another element, there are no intervening elements present. Further, in the specification, the word “on” or “above” means positioned on or below the object portion, and does not necessarily mean positioned on an upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

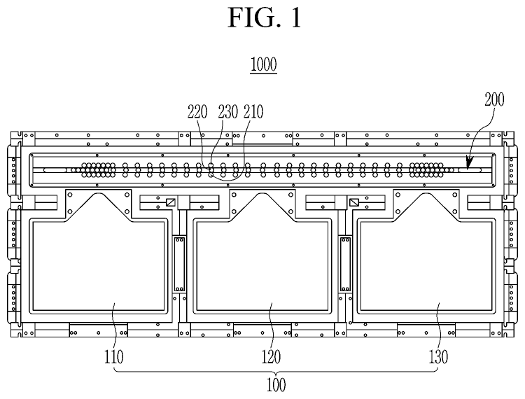

Herein, a deposition apparatus according to an embodiment will be described with reference to FIGS. 1 to 3. The deposition apparatus according to an embodiment may include a deposition apparatus for depositing an organic light emitting layer at a substrate, but the present disclosure is not limited thereto, and may include a deposition apparatus for depositing various materials at a substrate.

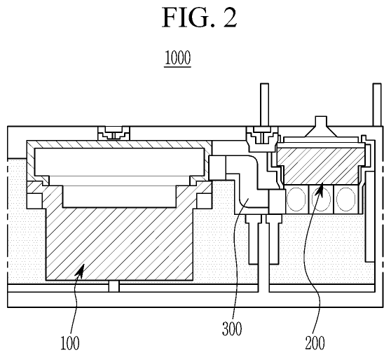

FIG. 1 is a plane view illustrating a deposition apparatus according to an embodiment; and FIG. 2 is a side view illustrating the deposition apparatus of FIG. 1.

Referring to FIGS. 1 and 2, a deposition apparatus 1000 according to an embodiment includes a vaporization portion 100, a first nozzle portion 200, and a pipe portion 300.

The vaporization portion 100 is connected to the first nozzle portion 200 through the pipe portion 300. The vaporization portion 100 vaporizes first, second, and third materials different from each other to be deposited at a substrate to supply the vaporized materials to the first nozzle portion 200. In an embodiment, the vaporization portion 100 includes a first crucible 110, a second crucible 120, and a third crucible 130 within the vaporization portion. The first crucible 110 vaporizes the first material stored in the first crucible 110 to supply the vaporized material to the first nozzle portion 200. The second crucible 120 is disposed adjacent to the first crucible 110, and vaporizes the second material stored in the second crucible 120 to supply the vaporized material to the first nozzle portion 200. The third crucible 130 is disposed adjacent to the second crucible 120, and vaporizes the third material stored in the third crucible 130 to supply the vaporized material to the first nozzle portion 200. In an embodiment, the second crucible 120 is disposed between the first crucible 110 and the third crucible 130, but the present disclosure is not limited thereto. The insides of the first crucible 110, the second crucible 120, and the third crucible 130 are spaced or separated from each other, and the first material, the second material, and the third material vaporized at the first crucible 110, the second crucible 120, and the third crucible 130 are not mixed inside the vaporization portion 100. In an embodiment, each of the first material, the second material, and the third material vaporized at each of the first crucible 110, the second crucible 120, and the third crucible 130 may be at least one of a host and a dopant to be mixed in a light emitting layer of the organic light emitting layer, but the present disclosure is not limited thereto.

The first nozzle portion 200 is connected to the vaporization portion 100 adjacent to the vaporization portion 100. The first nozzle portion 200 may discharge each of the first material, the second material, and the third material supplied from the vaporization portion 100 to the substrate through each of a first nozzle hole 210, a second nozzle hole 220, and a third nozzle hole 230, and may mix the discharged materials to deposit a light emitting layer of an organic light emitting layer at the substrate. The first nozzle portion 200 will be described further later.

The pipe portion 300 is connected between an upper portion of the vaporization portion 100 and a lower portion of the first nozzle portion 200. Each of the first material, the second material, and the third material vaporized to the upper portion of the vaporization portion 100 is moved to the lower portion of the first nozzle portion 200 through the pipe portion 300.

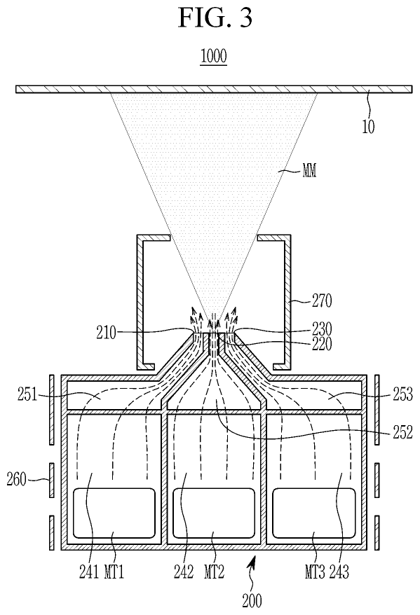

Herein, the first nozzle portion 200 will be described with reference to FIG. 3.

FIG. 3 is a longitudinal cross-sectional view illustrating the first nozzle portion 200 of the deposition apparatus 1000 according to an embodiment.

Referring to FIG. 3, the first nozzle portion 200 may discharge each of a first material MT1, a second material MT2, and a third material MT3 to the substrate 10 through each of the first nozzle hole 210, the second nozzle hole 220, and the third nozzle hole 230, and the discharged first, second, and third materials MT1, MT2, and MT3 may be mixed as a mixed material MM at an upper side of the first nozzle portion 200 to form the light emitting layer of the organic light emitting layer at the substrate 10. In an embodiment, each of the first material MT1, the second material MT2, and the third material MT3 may include any one of the host and the dopant mixed in the light emitting layer of the organic light emitting layer. For example, the first material MT1 may include a first host, and the second material MT2 may include the dopant. The third material MT3 may include a second host.

In an embodiment, the first nozzle portion 200 includes the first nozzle hole 210, the second nozzle hole 220, the third nozzle hole 230, a first connection portion 241, a second connection portion 242, a third connection portion 243, a first channel 251, a second channel 252, a third channel 253, a first heater 260, and a first angle limiting portion 270.

The first nozzle hole 210, the second nozzle hole 220, and the third nozzle hole 230 are disposed adjacent to each other, and are disposed at a same (same or substantially same) region.

The first nozzle hole 210 is adjacent to the second nozzle hole 220 and the third nozzle hole 230, and discharges the first material MT1 to the substrate 10. The first nozzle hole 210 communicates with the first connection portion 241 through the first channel 251, and the first material MT1 supplied to the first connection portion 241 is moved to the first nozzle hole 210 through the first channel 251 to be discharged to the substrate 10.

The second nozzle hole 220 is adjacent to the first nozzle hole 210 and the third nozzle hole 230, and discharges the second material MT2 to the substrate 10. The second nozzle hole 220 communicates with the second connection portion 242 through the second channel 252, and the second material MT2 supplied to the second connection portion 242 is moved to the second nozzle hole 220 through the second channel 252 to be discharged to the substrate 10. In an embodiment, the second nozzle hole 220 is disposed between the first nozzle hole 210 and the third nozzle hole 230, but the present disclosure is not limited thereto.

The third nozzle hole 230 is adjacent to the second nozzle hole 220, and discharges the third material MT3 to the substrate 10. The third nozzle hole 230 communicates with the third connection portion 243 through the third channel 253, and the third material MT3 supplied to the third connection portion 243 is moved to the third nozzle hole 230 through the third channel 253 to be discharged to the substrate 10.

The first connection portion 241 is connected to the vaporization portion 100 through the pipe portion 300 shown in FIG. 2 such that the first material MT1 is supplied from the vaporization portion 100. The first material MT1 supplied from the vaporization portion 100 through the first connection portion 241 and the first channel 251 is moved to the first nozzle hole 210. The first material MT1 vaporized through the inside of the first connection portion 241 moves to the first channel 251.

The second connection portion 242 is adjacent to the first connection portion 241. In an embodiment, the second connection portion 242 is disposed between the first connection portion 241 and the third connection portion 243, but the present disclosure is not limited thereto. The second connection portion 242 is connected to the vaporization portion 100 through the pipe portion 300 shown in FIG. 2 such that the second material MT2 is supplied from the vaporization portion 100. The second material MT2 supplied from the vaporization portion 100 through the second connection portion 242 and the second channel 252 is moved to the second nozzle hole 220. The second material MT2 vaporized through the inside of the second connection portion 242 moves to the second channel 252.

The third connection portion 243 is adjacent to the second connection portion 242. The third connection portion 243 is connected to the vaporization portion 100 through the pipe portion 300 shown in FIG. 2 such that the third material MT3 is supplied from the vaporization portion 100. The third material MT3 supplied from the vaporization portion 100 through the third connection portion 243 and the third channel 253 is moved to the third nozzle hole 230. The third material MT3 vaporized through the inside of the third connection portion 243 moves to the third channel 253.

The insides of the first connection portion 241, the second connection portion 242, and the third connection portion 243 are spaced or separated from each other, and the first material MT1, the second material MT2, and the third connection portion 243 vaporized through the first connection portion 241, the second connection portion 242, and the third connection portion 243 are not mixed inside the first nozzle portion 200.

The first channel 251 is connected between the first connection portion 241 to the first nozzle hole 210. The first material MT1 is moved from the first connection portion 241 to the first nozzle hole 210 through the first channel 251. In an embodiment, the first channel 251 is curved a plurality of times to be extended from the first connection portion 241 toward the first nozzle hole 210. In an embodiment, a shape of an inner space of the first channel 251 is symmetrical to a shape of an inner space of the third channel 253. An internal cross-sectional area of the first channel 251 decreases as the first channel 251 extends from the first connection portion 241 to the first nozzle hole 210. Accordingly, a flow velocity of the vaporized first material MT1 moving from the first connection portion 241 to the first nozzle hole 210 is improved such that a quantity of flow per hour of the first material MT1 discharged from the first nozzle hole 210 to the substrate 10 is improved.

The second channel 252 is adjacent to the first channel 251, and is disposed between the first channel 251 and the third channel 253. The second channel 252 is connected between the second connection portion 242 and the second nozzle hole 220. The second material MT2 is moved from the second connection portion 242 to the second nozzle hole 220 through the second channel 252. The second channel 252 extends from the second connection portion 242 toward the second nozzle hole 220. In an embodiment, a shape of an inner space of the second channel 252 is different from a shape of an inner space of the first channel 251 and a shape of an inner space of the third channel 253. An internal cross-sectional area of the second channel 252 decreases as the second channel 252 extends from the second connection portion 242 to the second nozzle hole 220. Accordingly, a flow velocity of the vaporized second material MT2 moving from the second connection portion 242 to the second nozzle hole 220 is improved such that a quantity of flow per hour of the second material MT2 discharged from the second nozzle hole 220 to the substrate 10 is improved.

The third channel 253 is adjacent to the second channel 252, and is connected between the third connection portion 243 and the third nozzle hole 230. The third material MT3 is moved from the third connection portion 243 to the third nozzle hole 230 through the third channel 253. In an embodiment, the third channel 253 is curved a plurality of times to be extended from the third connection portion 243 toward the third nozzle hole 230. In an embodiment, a shape of an inner space of the third channel 253 is symmetrical to a shape of an inner space of the first channel 251. In an embodiment, the shape of the inner space of the third channel 253 and the shape of the inner space of the first channel 251 are symmetrical to each other, and the second channel 252 is disposed between the first channel 251 and the third channel 253, such that the first nozzle hole 210, the second nozzle hole 220, and the third nozzle hole 230 are disposed at a same (same or substantially same) region. In an embodiment, the shape of the inner space of the third channel 253 is symmetrical to the shape of the inner space of the first channel 251. An internal cross-sectional area of the third channel 253 decreases as the third channel 253 extends from the third connection portion 243 to the third nozzle hole 230. Accordingly, a flow velocity of the vaporized third material MT3 moving from the third connection portion 243 to the third nozzle hole 230 is improved such that a quantity of flow per hour of the third material MT3 discharged from the third nozzle hole 230 to the substrate 10 is improved.

The first heater 260 heats the first connection portion 241, the first channel 251, the second connection portion 242, the second channel 252, the third connection portion 243, and the third channel 253. Since the first heater 260 heats the first connection portion 241, the first channel 251, the second connection portion 242, the second channel 252, the third connection portion 243, and the third channel 253, each of the vaporized first material MT1, the vaporized second material MT2, and the vaporized third material MT3 passing through the inside of the first nozzle portion 200 is easily moved to each of the first nozzle hole 210, the second nozzle hole 220, and the third nozzle hole 230 to be discharged to the substrate 10.

The first angle limiting portion 270 is disposed above or on the first nozzle portion 200, and surrounds the first nozzle hole 210, the second nozzle hole 220, and the third nozzle hole 230. The first angle limiting portion 270 may limit a radiation direction of the first material MT1, the second material MT2, and the third material MT3 discharged from the first nozzle hole 210, the second nozzle hole 220, and the third nozzle hole 230.

Thus, the first material MT1, the second material MT2, and the third material MT3 discharged from the first nozzle hole 210, the second nozzle hole 220, and the third nozzle hole 230 of the first nozzle portion 200 are mixed as the mixed material MM at an upper side of the first nozzle portion 200 such that the mixed material MM is deposited at the substrate 10 as the light emitting layer of the organic light emitting layer.

In an embodiment, since the deposition apparatus 1000 according to the embodiment includes the first nozzle portion 200 including the first nozzle hole 210 that discharges the first material MT1 including a host that may be mixed in the light emitting layer of the organic light emitting layer, the second nozzle hole 220 that discharges the second material MT2 including a dopant, and the third nozzle hole 230 that discharges the third material MT3 including another host, and the first nozzle hole 210, the second nozzle hole 220, and the third nozzle hole 230 are disposed at the same (same or substantially the same) region, the first material MT1, the second material MT2, and the third material MT3 discharged from the first nozzle hole 210, the second nozzle hole 220, and the third nozzle hole 230 are mixed as the mixed material MM at an upper side of the first nozzle portion 200 such that the mixed material MM is uniformly (uniformly or substantially uniformly) deposited at the substrate 10 as the light emitting layer of the organic light emitting layer.

That is, the deposition apparatus 1000 to uniformly form the organic light emitting layer on the substrate 10 is provided.

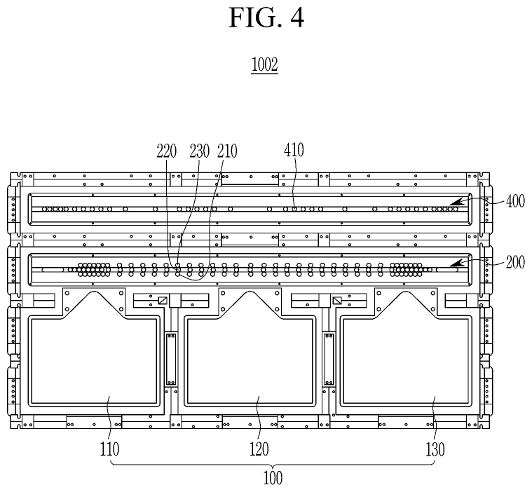

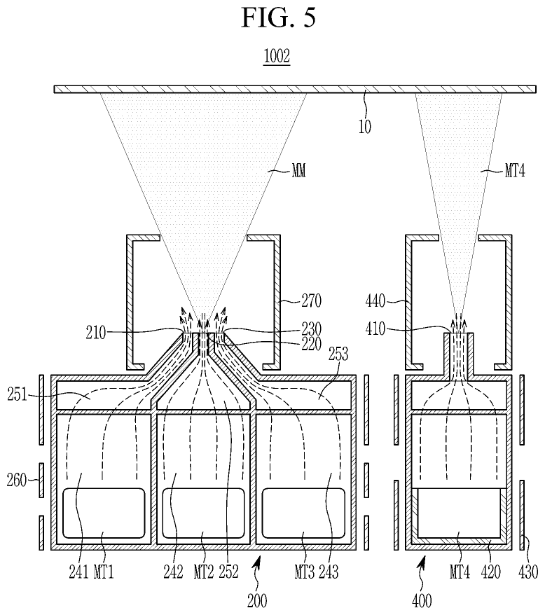

Herein, a deposition apparatus according to another embodiment will be described with reference to FIGS. 4 and 5. Herein, a portion different from the above-described embodiment will be described.

FIG. 4 is a plane view illustrating a deposition apparatus according to another embodiment; and FIG. 5 is a longitudinal cross-sectional view illustrating a first nozzle portion and a second nozzle portion of the deposition apparatus of FIG. 4.

Referring to FIGS. 4 and 5, a deposition apparatus 1002 according to an embodiment includes the vaporization portion 100, the first nozzle portion 200, and a second nozzle portion 400.

The first nozzle portion 200 may discharge each of the first material MT1, the second material MT2, and the third material MT3 to the substrate 10 through each of the first nozzle hole 210, the second nozzle hole 220, and the third nozzle hole 230, and the discharged materials may be mixed as the mixed material MM at an upper side of the first nozzle portion 200 to form the light emitting layer of the organic light emitting layer at the substrate 10.

The first nozzle portion 200 includes the first nozzle hole 210, the second nozzle hole 220, the third nozzle hole 230, the first connection portion 241, the second connection portion 242, the third connection portion 243, the first channel 251, the second channel 252, the third channel 253, the first heater 260, and the first angle limiting portion 270. The first nozzle hole 210, the second nozzle hole 220, and the third nozzle hole 230 are disposed adjacent to each other, and are disposed at the same (same or substantially the same) region.

The second nozzle portion 400 may be adjacent to the first nozzle portion 200, and may discharge a fourth material MT4 to the substrate 10 through a fourth nozzle hole 410 to form a hole injection layer, a hole transport layer, an electron transport layer, an electron injection layer, a buffer layer, or the like of the organic light emitting layer at the substrate 10.

The second nozzle portion 400 includes the fourth nozzle hole 410, a fourth crucible 420, a second heater 430, and a second angle limiting portion 440.

The fourth nozzle hole 410 discharges the fourth material MT4 vaporized in the fourth crucible 420 within the second nozzle portion 400 to the substrate 10.

The fourth crucible 420 stores and vaporizes the fourth material MT4 within the second nozzle portion 400.

The second heater 430 heats the fourth crucible 420 to vaporize the fourth material MT4 stored in the fourth crucible 420. Since the second heater 430 heats the fourth crucible 420, the vaporized fourth material MT4 passing through the inside of the second nozzle portion 400 is easily moved to the fourth nozzle hole 410 to be discharged to the substrate 10.

The second angle limiting portion 440 is disposed above or on the second nozzle portion 400, and surrounds the fourth nozzle hole 410. The second angle limiting portion 440 limits a radiation direction of the fourth material MT4 discharged from the fourth nozzle hole 410 such that the fourth material MT4 is suppressed from being mixed with the mixed material MM discharged from the first nozzle portion 200.

Thus, the first material MT1, the second material MT2, and the third material MT3 discharged from the first nozzle hole 210, the second nozzle hole 220, and the third nozzle hole 230 of the first nozzle portion 200 are mixed as the mixed material MM at an upper side of the first nozzle portion 200 such that the mixed material MM is deposited at the substrate 10 as the light emitting layer of the organic light emitting layer, and the fourth material MT4 discharged from the fourth nozzle hole 410 of the second nozzle portion 400 may be deposited at the substrate 10 as a hole injection layer, a hole transport layer, an electron transport layer, an electron injection layer, a buffer layer, or the like of the organic light emitting layer.

In the deposition apparatus 1002 according to an embodiment, the first material MT1, the second material MT2, and the third material MT3 discharged from the first nozzle hole 210, the second nozzle hole 220, and the third nozzle hole 230 of the first nozzle portion 200 are mixed as the mixed material MM at an upper side of the first nozzle portion 200 such that the mixed material MM is uniformly deposited at the substrate 10 as the light emitting layer of the organic light emitting layer, and the fourth material MT4 discharged from the fourth nozzle hole 410 of the second nozzle portion 400 may be uniformly deposited at the substrate 10 as the hole injection layer, the hole transport layer, the electron transport layer, the electron injection layer, the buffer layer, or the like of the organic light emitting layer.

That is, the deposition apparatus 1002 to uniformly form the organic light emitting layer on the substrate 10 is provided.

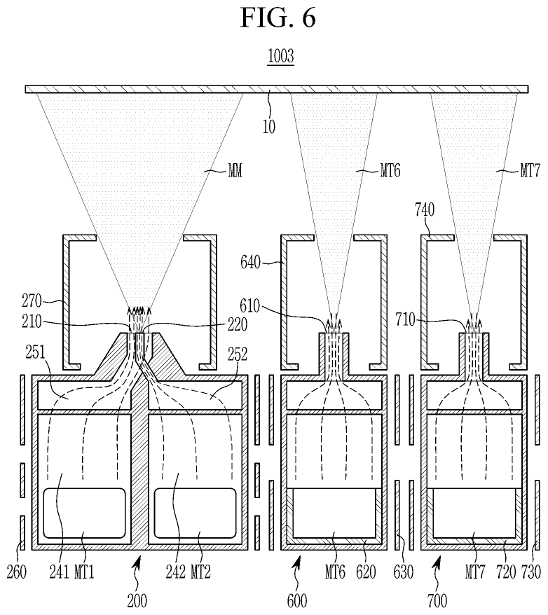

FIG. 6 is a longitudinal cross-sectional view illustrating a nozzle portion and another nozzle portion of a deposition apparatus according to another embodiment.

Referring to FIG. 6, a deposition apparatus 1003 according to an embodiment includes a first nozzle portion 200, at least one sixth nozzle portion 600, and at least one seventh nozzle portion 700.

The first nozzle portion 200 may discharge each of a first material MT1 and a second material MT2 to a substrate 10 through each of a first nozzle hole 210 and a second nozzle hole 220, and the discharged materials may be mixed as a mixed material MM at an upper side of the first nozzle portion 200 to form a light emitting layer of an organic light emitting layer at the substrate 10.

The first nozzle portion 200 includes the first nozzle hole 210, the second nozzle hole 220, a first connection portion 241, a second connection portion 242, a first channel 251, a second channel 252, a first heater 260, and a first angle limiting portion 270. The first nozzle hole 210 and the second nozzle hole 220 are disposed adjacent to each other, and are disposed at a same (same or substantially same) region.

In an embodiment, the first nozzle hole 210 may surround the second nozzle hole 220 on a plane, and a center of the second nozzle hole 220 may be concentric with a center of the first nozzle hole 210. Accordingly, the first material MT1 and the second material MT2 discharged from the first nozzle hole 210 and the second nozzle hole 220 may be easily mixed as the mixed material MM at an upper side of the first nozzle portion 200.

The sixth nozzle portion 600 may be adjacent to the first nozzle portion 200, and may discharge a sixth material MT6 to the substrate 10 through a sixth nozzle hole 610 to form a hole injection layer, a hole transport layer, an electron transport layer, an electron injection layer, a buffer layer, or the like of the organic light emitting layer at the substrate 10.

The sixth nozzle portion 600 includes the sixth nozzle hole 610, a sixth crucible 620, a sixth heater 630, and a sixth angle limiting portion 640.

The sixth nozzle hole 610 discharges the sixth material MT6 vaporized in the sixth crucible 620 disposed within the sixth nozzle portion 600 to the substrate 10.

The sixth crucible 620 stores and vaporizes the sixth material MT6 within the sixth nozzle portion 600.

The sixth heater 630 heats the sixth crucible 620 to vaporize the sixth material MT6 stored in the sixth crucible 620. Since the sixth heater 630 heats the sixth crucible 620, the vaporized sixth material MT6 passing through the inside of the sixth nozzle portion 600 is easily moved to the sixth nozzle hole 610 to be discharged to the substrate 10.

The sixth angle limiting portion 640 is disposed above or on the sixth nozzle portion 600, and surrounds the sixth nozzle hole 610. The sixth angle limiting portion 640 limits a radiation direction of the sixth material MT6 discharged from the sixth nozzle hole 610 such that the sixth material MT6 is suppressed from being mixed with the mixed material MM discharged from the first nozzle portion 200.

The seventh nozzle portion 700 may be adjacent to the sixth nozzle portion 600, and may discharge a seventh material MT7 to the substrate 10 through a seventh nozzle hole 710 to form a hole injection layer, a hole transport layer, an electron transport layer, an electron injection layer, a buffer layer, or the like of the organic light emitting layer at the substrate 10.

The seventh nozzle portion 700 includes the seventh nozzle hole 710, a seventh crucible 720, a seventh heater 730, and a seventh angle limiting portion 740.

The seventh nozzle hole 710 discharges the seventh material MT7 vaporized in the seventh crucible 720 within the seventh nozzle portion 700 to the substrate 10.

The seventh crucible 720 stores and vaporizes the seventh material MT7 in the seventh nozzle portion 700.

The seventh heater 730 heats the seventh crucible 720 to vaporize the seventh material MT7 stored in the seventh crucible 720. Since the seventh heater 730 heats the seventh crucible 720, the vaporized seventh material MT7 passing through the inside of the seventh nozzle portion 700 is easily moved to the seventh nozzle hole 710 to be discharged to the substrate 10.

The seventh angle limiting portion 740 is disposed above or on the seventh nozzle portion 700, and surrounds the seventh nozzle hole 710. The seventh angle limiting portion 740 limits a radiation direction of the seventh material MT7 discharged from the seventh nozzle hole 710 such that the seventh material MT7 is suppressed from being mixed with the sixth material MT6 discharged from the sixth nozzle portion 600.

Thus, the first material MT1 and the second material MT2 discharged from the first nozzle hole 210 and the second nozzle hole 220 of the first nozzle portion 200 are mixed as the mixed material MM at an upper side of the first nozzle portion 200 such that the mixed material MM is deposited at the substrate 10 as the light emitting layer of the organic light emitting layer, the sixth material MT6 discharged from the sixth nozzle hole 610 of the sixth nozzle portion 600 may be deposited at the substrate 10 as the hole injection layer, the hole transport layer, the electron transport layer, the electron injection layer, the buffer layer, or the like of the organic light emitting layer, and the seventh material MT7 discharged from the seventh nozzle hole 710 of the seventh nozzle portion 700 may be deposited at the substrate 10 as the hole injection layer, the hole transport layer, the electron transport layer, the electron injection layer, the buffer layer, or the like of the organic light emitting layer.

In the deposition apparatus 1003 according to an embodiment, the first material MT1 and the second material MT2 discharged from the first nozzle hole 210 and the second nozzle hole 220 of the first nozzle portion 200 are mixed as the mixed material MM at an upper side of the first nozzle portion 200 such that the mixed material MM is uniformly deposited at the substrate 10 as the light emitting layer of the organic light emitting layer, the sixth material MT6 discharged from the sixth nozzle hole 610 of the sixth nozzle portion 600 may be uniformly deposited at the substrate 10 as the hole injection layer, the hole transport layer, the electron transport layer, the electron injection layer, the buffer layer, or the like of the organic light emitting layer, and the seventh material MT7 discharged from the seventh nozzle hole 710 of the seventh nozzle portion 700 may be uniformly deposited at the substrate 10 as the hole injection layer, the hole transport layer, the electron transport layer, the electron injection layer, the buffer layer, or the like of the organic light emitting layer.

That is, the deposition apparatus 1003 to uniformly form the organic light emitting layer on the substrate 10 is provided.

While the present disclosure has been described in connection with what are presently considered to be some practical embodiments, it is to be understood that the disclosure is not limited to the disclosed embodiments, but, on the contrary, is intended to cover various modifications and equivalent arrangements included within the spirit and scope of the appended claims.

What is claimed is:

1. A deposition apparatus comprising:
a vaporization portion to vaporize a first material, a second material, and a third material different from each other; and
a first nozzle portion connected adjacent to the vaporization portion,
wherein the first nozzle portion comprises:
a first nozzle hole to discharge the first material;
a second nozzle hole adjacent to the first nozzle hole and to discharge the second material; and
a third nozzle hole adjacent to the first nozzle hole and the second nozzle hole and to discharge the third material.

2. The deposition apparatus of claim 1, wherein the vaporization portion comprises:
a first crucible to vaporize the first material;
a second crucible adjacent to the first crucible and to vaporize the second material; and
a third crucible adjacent to the second crucible and to vaporize the third material.

3. The deposition apparatus of claim 2, wherein insides of the first crucible, the second crucible, and the third crucible are spaced from each other.

4. The deposition apparatus of claim 1, wherein the first nozzle portion further comprises:
a first connection portion connected to the vaporization portion and through which the first material passes;
a second connection portion adjacent to the first connection portion, connected to the vaporization portion, and through which the second material passes; and
a third connection portion adjacent to the second connection portion, connected to the vaporization portion, and through which the third material passes.

5. The deposition apparatus of claim 4, wherein insides of the first connection portion, the second connection portion, and the third connection portion are spaced from each other.

6. The deposition apparatus of claim 4, wherein the first nozzle portion further comprises:
a first channel connected between the first connection portion and the first nozzle hole;
a second channel adjacent to the first channel and connected between the second connection portion and the second nozzle hole; and
a third channel adjacent to the second channel and connected between the third connection portion and the third nozzle hole.

7. The deposition apparatus of claim 6, wherein insides of the first channel, the second channel, and the third channel are spaced from each other.

8. The deposition apparatus of claim 6, wherein the second channel is between the first channel and the third channel.

9. The deposition apparatus of claim 8, wherein a shape of an inner space of the first channel is symmetrical to a shape of an inner space of the third channel, and a shape of an inner space of the second channel is different from the shape of the inner space of the first channel and the shape of the inner space of the third channel.

10. The deposition apparatus of claim 6, wherein an internal cross-sectional area of the first channel decreases as the first channel extends from the first connection portion to the first nozzle hole, an internal cross-sectional area of the second channel decreases as the second channel extends from the second connection portion to the second nozzle hole, and an internal cross-sectional area of the third channel decreases as the third channel extends from the third connection portion to the third nozzle hole.

11. The deposition apparatus of claim 6, wherein the first nozzle portion further comprises a first heater to heat the first connection portion, the first channel, the second connection portion, the second channel, the third connection portion, and the third channel.

12. The deposition apparatus of claim 1, wherein the first nozzle hole, the second nozzle hole, and the third nozzle hole of the first nozzle portion are located at a same region.

13. The deposition apparatus of claim 1, wherein after the first material, the second material, and the third material are discharged from the first nozzle hole, the second nozzle hole, and the third nozzle hole, the discharged first, second, and third materials are mixed at an upper side of the first nozzle portion.

14. The deposition apparatus of claim 1, wherein the first nozzle portion further comprises a first angle limiting portion around the first nozzle hole, the second nozzle hole, and the third nozzle hole.

15. The deposition apparatus of claim 1, further comprising a pipe portion connected between an upper portion of the vaporization portion and a lower portion of the first nozzle portion.

16. The deposition apparatus of claim 1, further comprising a second nozzle portion adjacent to the first nozzle portion and comprising a fourth nozzle hole to discharge a fourth material.

17. The deposition apparatus of claim 16, wherein the second nozzle portion further comprises a fourth crucible to vaporize the fourth material.

18. The deposition apparatus of claim 17, wherein the second nozzle portion further comprises a second heater to heat the fourth crucible.

19. The deposition apparatus of claim 16, wherein the second nozzle portion further comprises a second angle limiting portion around the fourth nozzle hole.

20. A deposition apparatus comprising:
a vaporization portion to vaporize a plurality of different materials;
a nozzle portion connected adjacent to the vaporization portion and comprising a nozzle hole to discharge a material of the plurality of materials and another nozzle hole adjacent to the nozzle hole and to discharge another material of the plurality of materials; and
at least one other nozzle portion adjacent to the nozzle portion and comprising another nozzle hole to discharge another material.
